(19) United States
(12) Patent Application Publication
(10) Pub. No.: US 2026/0136602 A1
(43) Pub. Date: May 14, 2026

(54) MID OF LINE CONTACT STRUCTURE FOR NANOSHEET TRANSISTOR

(71) Applicant: International Business Machines Corporation, Armonk, NY (US)

(72) Inventors: Shahab Siddiqui, Clifton Park, NY (US); Ravikumar Ramachandran, Pleasantville, NY (US); Anton Tokranov, Halfmoon, NY (US); Christopher D Sheraw, Altamont, NY (US); PIETRO MONTANINI, Albany, NY (US); Genevieve Beique, Latham, NY (US); Eric Miller, Albany, NY (US); Tushar Gupta, Albany, NY (US); Mahender Kumar, Clifton Park, NY (US)

(21) Appl. No.: 18/947,742

(22) Filed: Nov. 14, 2024

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 84/013; H10D 84/0149; H10D 84/038; H10D 84/83

(57) ABSTRACT

Embodiments of present invention provide a semiconductor structure. The semiconductor structure includes a transistor having a metal gate and a dielectric cap on top of the metal gate; and a source/drain contact directly on top of a source/drain region of the transistor, where the source/drain contact has a top portion of a first width in a length direction of the metal gate and a bottom portion of a second width in the length direction of the metal gate with the first width being narrower than the second width. A method of forming the same is also provided.

### BACKGROUND

The present application relates to manufacturing of semiconductor integrated circuits. More particularly, it relates to method of forming mid-of-line contact structure with gate contact in active region and the structure formed thereby.

As semiconductor industry moves towards smaller node, field-effect-transistors (FETs) are aggressively scaled to fit into reduced footprint or real estate with increased device density. For example, contact to the gate of a transistor may be placed in or near an active region of the transistor so as not to occupy extra real estate of the semiconductor chip. However, placing the gate contact in active region may increase the risk of shorting between the gate contact and source/drain contact due to their proximity.

### SUMMARY

Embodiments of present invention provide a semiconductor structure. The semiconductor structure includes a transistor having a metal gate and a dielectric cap on top of the metal gate; and a source/drain (S/D) contact directly on top of a S/D region of the transistor, where the S/D contact has a top portion of a first width in a length direction of the metal gate and a bottom portion of a second width in the length direction of the metal gate with the first width being narrower than the second width.

In one embodiment, the top portion of the S/D contact has a bottom that is below a top surface of the dielectric cap, and a width of the S/D contact changes from the first width to the second width at the bottom of the top portion of the S/D contact.

In another embodiment, sidewalls of the bottom portion of the S/D contact include a metallic liner, sidewalls of the top portion of the S/D contact do not have the metallic liner and are directly surrounded by a dielectric spacer, and the dielectric spacer and the metallic liner are substantially vertically aligned.

According to one embodiment, the semiconductor structure further includes a gate contact on top of the metal gate and surrounded by the dielectric cap above the metal gate, where a distance from the gate contact to the S/D contact is greater at a top of the gate contact than at a bottom of the gate contact.

According to another embodiment, the semiconductor structure further includes a dielectric layer on top of the dielectric cap, the dielectric layer surrounding the gate contact and surrounding the top portion of the S/D contact through a dielectric spacer.

In one embodiment, the gate contact is above the metal gate and vertically over an active region of the transistor.

Embodiments of present invention further provide a method of forming a semiconductor structure. The method includes creating an opening above and exposing a source/drain (S/D) region of a transistor; forming a first portion of a S/D contact at a lower portion of the opening with a first width, the first portion directly contacting the S/D region; forming dielectric spacers at an upper portion of the opening, thereby narrowing the opening in a length direction of a metal gate of the transistor; and forming a second portion of the S/D contact in the upper portion of the opening with a second width directly on top of the first portion of the S/D contact, the second width being narrower than the first width.

According to one embodiment, the method further includes forming the transistor by forming the metal gate surrounding a set of nanosheets; and forming a dielectric cap on top of the metal gate, where a top surface of the first portion of the S/D contact is above a top surface of the metal gate and below a top surface of the dielectric cap.

In one embodiment, creating the opening includes forming a dielectric liner lining sidewalls of the metal gate and a top surface of the S/D region; forming a dielectric layer on top of the dielectric liner; removing a portion of the dielectric layer vertically above the S/D region; and removing a portion of the dielectric liner exposed by the removed portion of the dielectric layer to expose the S/D region.

In another embodiment, forming the first portion of the S/D contact includes forming a metallic liner lining the opening; depositing a conductive material on top of the metallic liner; and recessing the conductive material and the metallic liner to a level below the top surface of the dielectric cap, thereby forming the first portion of the S/D contact.

According to one embodiment, the method further includes, before forming the first portion of the S/D contact, performing ion implantation into the exposed S/D regions; and subjecting the transistor to an anneal process.

According to another embodiment, the method further includes forming a gate contact in contact with the metal gate, the gate contact being partially surrounded by the dielectric cap and formed vertically above an active region of the transistor.

Embodiments of present invention provide a semiconductor structure. The structure includes a first metal gate and a second metal gate surrounding a first set of nanosheets and a second set of nanosheets respectively; a source/drain region between the first and the second set of nanosheets; and a source/drain contact directly on top of the source/drain region, where the source/drain contact has a first portion of a first width and a second portion of a second width, the second portion being on top of the first portion and the second width being narrower than the first width with the first and the second width being measured in a length direction of the first and the second metal gate.

According to one embodiment, the semiconductor structure further includes a dielectric cap on top of the first metal gate and a dielectric layer on top of the dielectric cap, where a bottom of the second portion of the source/drain contact is at least below a bottom surface of the dielectric layer.

According to another embodiment, the semiconductor structure further includes a gate contact, the gate contact being surrounded by the dielectric layer, by the dielectric cap, and in contact with the first metal gate.

In one embodiment, the first portion of the source/drain contact has a metallic liner at sidewalls thereof and the second portion of the source/drain contact is directly surrounded by a dielectric spacer, the metallic liner and the dielectric spacer are substantially vertically aligned.

In another embodiment, the second portion of the source/drain contact is separated from the gate contact by at least the dielectric spacer and a sidewall gate spacer that surrounds the first metal gate.

In yet another embodiment, the dielectric spacer and the sidewall gate spacer are separated by a dielectric liner.

According to one embodiment, the dielectric spacer has a thickness H2 ranging from about 1 nm to about 5 nm while the second portion of the source/drain contact and the gate contact are separated by about 5 nm to about 9 nm.

According to another embodiment, the dielectric layer has a thickness H0 ranging from about 10 nm to about 25 nm.

### BRIEF DESCRIPTION OF THE DRAWINGS

The present invention will be understood and appreciated more fully from the following detailed description of embodiments of present invention, taken in conjunction with accompanying drawings of which:

FIG. 1 is a demonstrative illustration of cross-sectional view of a semiconductor structure at a step of manufacturing thereof according to embodiments of present invention;

FIG. 2 is a demonstrative illustration of cross-sectional view of a semiconductor structure at a step of manufacturing thereof, following the step illustrated in FIG. 1, according to embodiments of present invention;

FIG. 3 is a demonstrative illustration of cross-sectional view of a semiconductor structure at a step of manufacturing thereof, following the step illustrated in FIG. 2, according to embodiments of present invention;

FIG. 4 is a demonstrative illustration of cross-sectional view of a semiconductor structure at a step of manufacturing thereof, following the step illustrated in FIG. 3, according to embodiments of present invention;

FIG. 5 is a demonstrative illustration of cross-sectional view of a semiconductor structure at a step of manufacturing thereof, following the step illustrated in FIG. 4, according to embodiments of present invention;

FIG. 6 is a demonstrative illustration of cross-sectional view of a semiconductor structure at a step of manufacturing thereof, following the step illustrated in FIG. 5, according to embodiments of present invention;

FIG. 7 is a demonstrative illustration of cross-sectional view of a semiconductor structure at a step of manufacturing thereof, following the step illustrated in FIG. 6, according to embodiments of present invention;

FIG. 8 is a demonstrative illustrations of cross-sectional view of a semiconductor structure at a step of manufacturing thereof, following the step illustrated in FIG. 7, according to embodiments of present invention; and

FIG. 9 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

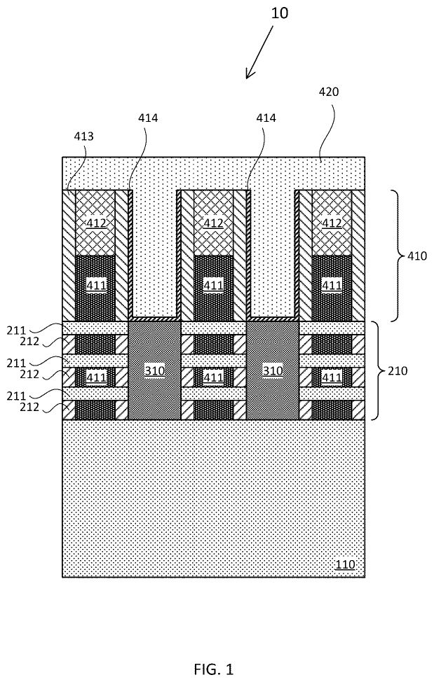

FIG. 1 is a demonstrative illustration of cross-sectional view of a semiconductor structure 10 in a step of manufacturing thereof according to one embodiment of present invention. As a non-limiting example, the semiconductor structure 10 may include one or more nanosheet (NS) transistors, and the cross-section is made along a length of gate of the one or more NS transistors.

More particularly, embodiments of present invention provide receiving or providing the semiconductor structure 10. The semiconductor structure 10 may include a semiconductor substrate 110 and a set of NS transistors 210 formed on top of the semiconductor substrate 110. The semiconductor substrate 110 may be a bulk silicon (Si) substrate, a bulk germanium (Ge) substrate, a silicon-germanium (SiGe) substrate, a silicon-on-insulator (SOI) substrate, a silicon-germanium-on-insulator (SGOI), and/or other suitable substrate. As is demonstratively illustrated in FIG. 1, the semiconductor substrate 110 may be a bulk Si substrate.

Each of the set of NS transistors 210 may include a set of Si nanosheets 211 surrounded by one of metal gates 411. In other words, the metal gates 411 may be formed in surrounding the set of Si nanosheets 211. Source/drain (S/D) regions 310 may be epitaxially formed in between the set of NS transistors 210 and more particularly between different sets of Si nanosheets 211. The S/D regions 310 may, in some embodiments, serve as shared S/D regions of some of the set of NS transistors 210. Inner spacers 212 may be formed vertically between individual Si nanosheets to separate and/or isolate the metal gates 411 from the S/D regions 310. The metal gates 411 may be covered, on top thereof, by a dielectric cap 412 with sidewall gate spacers 413 formed at sidewalls of the metal gates 411 and sidewalls of the dielectric cap 412. The dielectric cap 412 provides insulation for the metal gates 411.

Embodiments of present invention further provide forming a dielectric liner 414 lining the metal gates 411 along sidewall gate spacers 413 in a region 410 above the S/D regions 310 and between the metal gates 411. The dielectric liner 414 may be known as a poly-open-CMP (POC) liner and may cover the S/D regions 310 as well. The dielectric liner 414 may serve as an etch-stop-layer (ESL) later during process of manufacturing. Next, a dielectric layer 420 may be formed, for example, through a deposition process to fill the space or opening between the metal gates 411 on top of the S/D regions 310. The dielectric layer 420 may be formed on top of the metal gates 411 as well, via the dielectric cap 412. The dielectric layer 420 may include material such as, for example, silicon-nitride (SiN), silicon-oxide (SiOx), and/or other suitable materials.

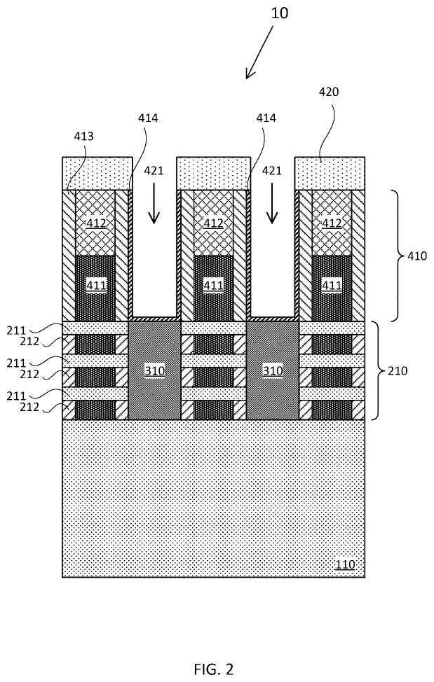

FIG. 2 is a demonstrative illustration of cross-sectional view of a semiconductor structure 10 in a step of manufacturing thereof, following the step illustrated in FIG. 1, according to one embodiment of present invention. More particularly, embodiments of present invention provide selectively removing portions of the dielectric layer 420 that are above the S/D regions 310 in-between the metal gates 411. In doing so, a hard mask may for example be first formed through a lithographic patterning process on top of the dielectric layer 420 with openings vertically above the S/D regions 310. Next, a selective etch process, such as a reactive-ion-etch (RIE) process, may be applied to etch the dielectric layer 420 through the openings in the hard mask thereby creating openings 421, between the metal gates 411, that expose the dielectric liner 414. In one embodiment, the dielectric layer 420 may be a material of SiOx and the dielectric liner 414 may be a material of SiN and the etch process may be selective to the SiOx material and stop at the SiN material of dielectric liner 414.

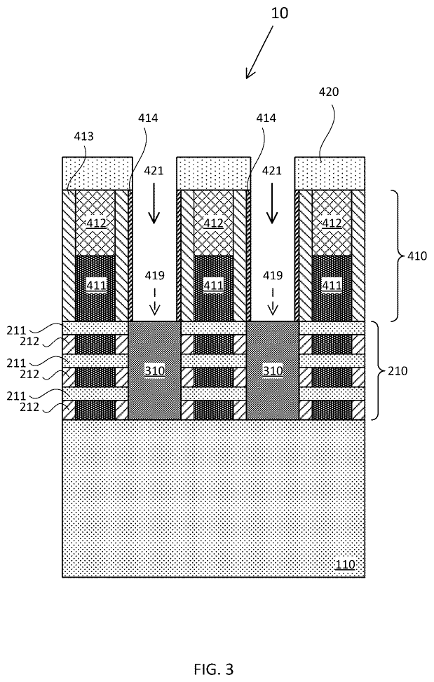

FIG. 3 is a demonstrative illustration of cross-sectional view of a semiconductor structure 10 in a step of manufacturing thereof, following the step illustrated in FIG. 2, according to one embodiment of present invention. More particularly, embodiments of present invention provide applying an anisotropic and/or directional etch process to remove horizontal portions of the dielectric liner 414, thereby exposing the underneath S/D regions 310, while leaving vertical portions of the dielectric liner 414 substantially unaffected. The substantially unaffected vertical portions of the dielectric liner 414 may therefore protect sidewalls of the metal gates 411 from subsequent processing steps. Next, embodiments of present invention provide performing ion implantation 419 of impurities, such as positive or negative ions depending on the type of transistor being manufactured, into the S/D regions 310 through the openings 421. After the ion implantation 419, the set of transistors and in particular the S/D regions 310 of the set of NS transistors 210 may be subjected to an anneal process to drive the ions further into the S/D regions 310.

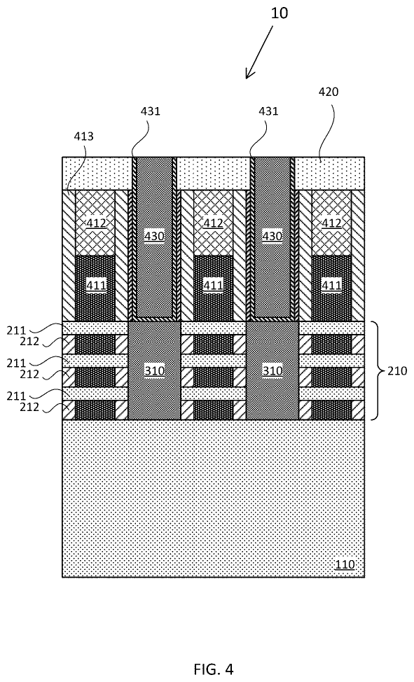

FIG. 4 is a demonstrative illustration of cross-sectional view of a semiconductor structure 10 in a step of manufacturing thereof, following the step illustrated in FIG. 3, according to one embodiment of present invention. More particularly, embodiments of present invention provide forming metallic liners 431 lining the openings 421 including on top of the S/D regions 310 and the vertical portions of the dielectric liner 414. The metallic liners 431 may include material such as, for example, titanium (Ti), tantalum (Ta), titanium-nitride (TiN), tantalum-nitride (TaN), or a combination thereof. The metallic liner 431 may be deposited to help improve adhesiveness of S/D contacts, to be formed subsequently, to the openings 421 and particularly to the underneath epitaxial S/D regions 310. Next, a conductive material such as, for example, tungsten (W), copper (Cu), cobalt (Co), and/or other suitable materials may be deposited onto the remaining portions of the openings 421 thereby forming a conductive core 430 of S/D contacts. Next, a chemical-mechanical-polishing (CMP) process may be applied to planarize a top surface of the conductive core 430 such that the conductive core 430 becomes coplanar with top surface of the dielectric layer 420.

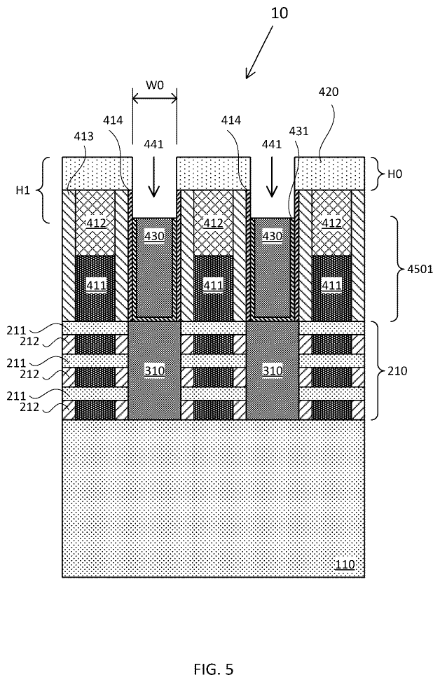

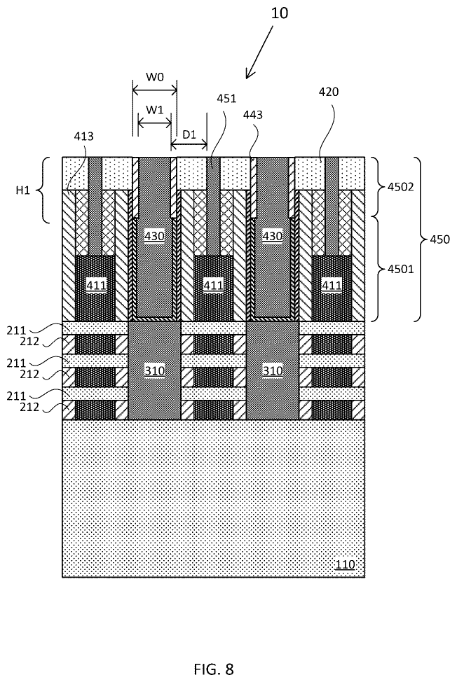

FIG. 5 is a demonstrative illustration of cross-sectional view of a semiconductor structure 10 in a step of manufacturing thereof, following the step illustrated in FIG. 4, according to one embodiment of present invention. More particularly, embodiments of present invention provide recessing the conductive core 430, as well as the metallic liner 431 that surrounds the conductive core 430, to form a first portion 4501 (i.e., a lower portion) of a S/D contact 450 (see FIG. 8). The first portion 4501 of the S/D contact 450 formed thereby may have a top surface that is below a top surface of the dielectric cap 412 on top of the metal gate 411. In other words, the conductive core 430 and the metallic liner 431 surrounding the conductive core 430 may be recessed to a level below the dielectric layer 420 to help mitigate a potential shorting risk, which is discussed below in more details. The recessing of the conductive core 430 and the metallic liner 431 may help create openings 441 having a depth H1 that is deeper than a thickness H0 of the dielectric layer 420. For example, thickness H0 of the dielectric layer 420 may be between about 10 nm to about 25 nm and depth H1 may be larger or deeper than 10 nm and may be larger or deeper than 25 nm. The openings 441 may be surrounded at a bottom portion, below the dielectric layer 420, by the dielectric liner 414 and surrounded at a top portion by the dielectric layer 420. The openings 441 and the first portion 4501 of the S/D contact 450 may have a width W0 that is measured along a length direction of the metal gates 411. In one embodiment, width W0 may be between about 10 nm and about 50 nm.

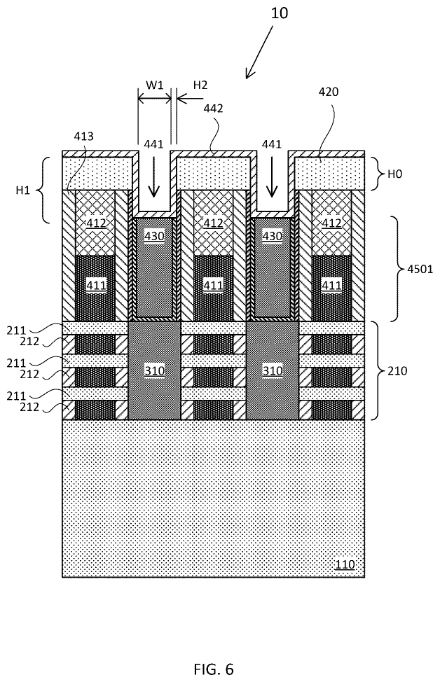

FIG. 6 is a demonstrative illustration of cross-sectional view of a semiconductor structure 10 in a step of manufacturing thereof, following the step illustrated in FIG. 5, according to one embodiment of present invention. More particularly, embodiments of present invention provide forming dielectric spacers at sidewalls of the openings 441 to narrow down the width W0 of the openings 441. The narrowing of width W0 of the openings 441 provides more room or space for forming gate contacts with reduced risk of shorting to the S/D contacts 450. In doing so, embodiments of present invention provide forming a conformal dielectric layer 442 through, for example, an atomic-layer-deposition (ALD) process, a chemical-vapor-deposition (CVD) process, or a physical-vapor-deposition (PVD) process. The conformal dielectric layer 442 formed thereby may have a thickness H2, which ranges from about 1 nm to about 5 nm, and cover or line the opening 441 at sidewalls and bottoms thereof.

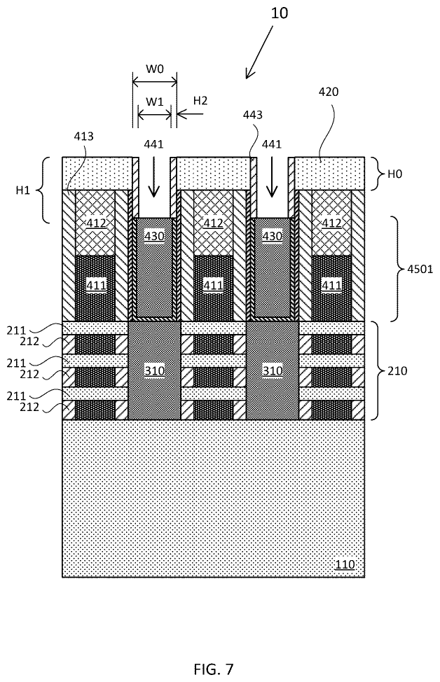

FIG. 7 is a demonstrative illustration of cross-sectional view of a semiconductor structure 10 in a step of manufacturing thereof, following the step illustrated in FIG. 6, according to one embodiment of present invention. More particularly, embodiments of present invention provide applying an anisotropic or directional etch process such as a RIE process to remove horizontal portions of the conformal dielectric layer 442, thereby leaving vertical portions of the conformal dielectric layer 442 at sidewalls of the openings 441 to form dielectric spacers 443. The dielectric spacers 443 may be substantially and vertically aligned with the metallic liner 431 along sidewalls of the opening 441 and an outer surface of the metallic liner 431. The formation of the dielectric spacers 443 effectively reduces the width of the openings 441 from W0 to W1 and increases a distance between the S/D contact 450 and a gate contact 451 (see FIG. 8). More particularly, a potential shorting risk between the S/D contact 450 and the gate contact 451 is reduced by the increase in distance, in the amount of thickness H2 of the dielectric spacers 443, between a second portion 4502 (i.e., an upper portion) of the S/D contact 450 (see FIG. 8) and the gate contact 451.

FIG. 8 is a demonstrative illustration of cross-sectional view of a semiconductor structure 10 in a step of manufacturing thereof, following the step illustrated in FIG. 7, according to one embodiment of present invention. More particularly, embodiments of present invention provide filling the remaining portion of the openings 441, which has the narrowed or reduced width W1 (compared with the width W0) that may range from about 5 nm to about 49 nm, with a conductive material to form the second portion 4502 (i.e., an upper portion) of the S/D contact 450. The second portion 4502 of the S/D contact 450 may thus have the width W1, measured along a length direction of the metal gates 411, that ranges from about 5 nm to about 49 nm as well.

Additionally, one or more gate contacts such as a gate contact 451 may be formed, or may already be formed, to be in contact with one or mor of the metal gates 411. The gate contact 451 may be formed through the dielectric layer 420 and the dielectric cap 412 to be surrounded by both the dielectric layer 420 and the dielectric cap 412. The gate contact 451 may be separated or insulated from the S/D contact 450 by a distance and the distance may be greater at a top than at a bottom of the gate contact 451. More particularly, a distance from the gate contact 451 to the second portion 4502 of the S/D contact 450 may be greater than a distance from the gate contact 451 to the first portion 4501 of the S/D contact 450. Since a shorting is more likely to happen in a region of the dielectric layer 420, than in a region of the dielectric cap 412, the increase in distance between the second portion 4502 of the S/D contact 450 and the gate contact 451 helps reduce the shorting risk.

As being discussed above, because of the use of the dielectric spacers 443, a distance D1 between the second portion 4502 of the S/D contact 450 and the gate contact 451 may be increased by the thickness H2 of the dielectric spacers 443, and the potential issue of shorting between the two may be, at least partially, mitigated. In one embodiment, with the thickness H2 ranging from about 1 nm to about 5 nm, the distance D1 may be increased to a range from about 5 nm to about 9 nm, which greatly reduces the risk of shorting.

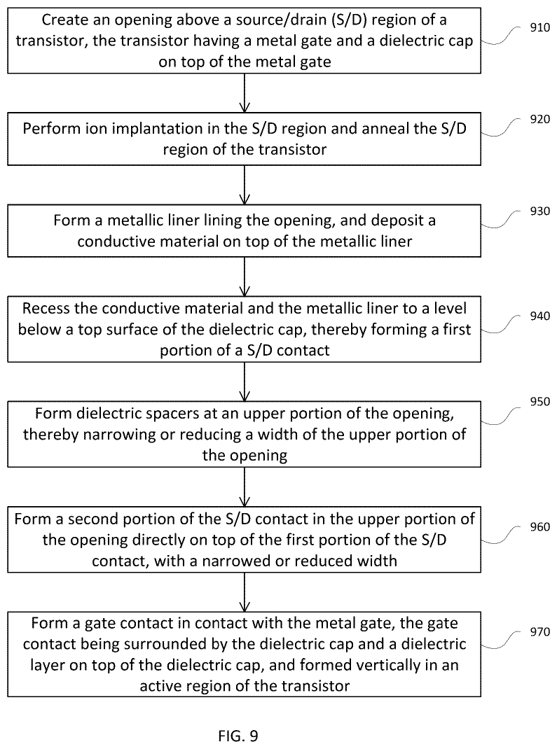

FIG. 9 is a demonstrative illustration of a flow-chart of a method of manufacturing a semiconductor structure according to embodiments of present invention. The method includes (910) creating an opening above a source/drain (S/D) region of a transistor, the transistor having a metal gate and a dielectric cap on top of the metal gate; (920) performing ion implantation in the S/D region and annealing the S/D region of the transistor; (930) forming a metallic liner lining the opening, and depositing a conductive material on top of the metallic liner; (940) recessing the conductive material and the metallic liner to a level below a top surface of the dielectric cap, thereby forming a first portion of a S/D contact; (950) forming dielectric spacers at an upper portion of the opening, thereby narrowing or reducing a width of the upper portion of the opening; (960) forming a second portion of the S/D contact in the upper portion of the opening directly on top of the first portion of the S/D contact with a narrowed or reduced width; and (970) forming a gate contact in contact with the metal gate, the gate contact being surrounded by the dielectric cap and a dielectric layer on top of the dielectric cap, and formed vertically in an active region of the transistor.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a transistor having a metal gate and a dielectric cap on top of the metal gate; and
a source/drain contact directly on top of a source/drain region of the transistor,
wherein the source/drain contact has a top portion of a first width in a length direction of the metal gate and a bottom portion of a second width in the length direction of the metal gate with the first width being narrower than the second width.

2. The semiconductor structure of claim 1, wherein the top portion of the source/drain contact has a bottom that is below a top surface of the dielectric cap; and the source/drain contact has a width that changes from the first width to the second width at the bottom of the top portion of the source/drain contact.

3. The semiconductor structure of claim 1, wherein sidewalls of the bottom portion of the source/drain contact include a metallic liner, sidewalls of the top portion of the source/drain contact do not have the metallic liner and are directly surrounded by a dielectric spacer, and the dielectric spacer and the metallic liner are substantially vertically aligned.

4. The semiconductor structure of claim 1, further comprising a gate contact on top of the metal gate and surrounded by the dielectric cap above the metal gate, wherein a distance from the gate contact to the source/drain contact is greater at a top of the gate contact than at a bottom of the gate contact.

5. The semiconductor structure of claim 4, further comprising a dielectric layer on top of the dielectric cap, the dielectric layer surrounding the gate contact and surrounding the top portion of the source/drain contact through a dielectric spacer.

6. The semiconductor structure of claim 4, wherein the gate contact is above the metal gate and vertically over an active region of the transistor.

7. A method of forming a semiconductor structure comprising:
creating an opening above and exposing a source/drain region of a transistor;
forming a first portion of a source/drain contact at a lower portion of the opening with a first width, the first portion directly contacting the source/drain region;
forming dielectric spacers at an upper portion of the opening, thereby narrowing the opening in a length direction of a metal gate of the transistor; and
forming a second portion of the source/drain contact in the upper portion of the opening with a second width directly on top of the first portion of the source/drain contact, the second width being narrower than the first width.

8. The method of claim 7, further comprising:
forming the transistor by forming the metal gate surrounding a set of nanosheets; and
forming a dielectric cap on top of the metal gate,
wherein a top surface of the first portion of the source/drain contact is above a top surface of the metal gate and below a top surface of the dielectric cap.

9. The method of claim 8, wherein creating the opening comprises:
forming a dielectric liner lining sidewalls of the metal gate and a top surface of the source/drain region;
forming a dielectric layer on top of the dielectric liner;
removing a portion of the dielectric layer vertically above the source/drain region; and
removing a portion of the dielectric liner exposed by the removal of the portion of the dielectric layer to expose the source/drain region.

10. The method of claim 9, wherein forming the first portion of the source/drain contact comprises:
forming a metallic liner lining the opening;
depositing a conductive material on top of the metallic liner; and
recessing the conductive material and the metallic liner to a level below the top surface of the dielectric cap, thereby forming the first portion of the source/drain contact.

11. The method of claim 7, further comprising, before forming the first portion of the source/drain contact:
performing ion implantation into the exposed source/drain regions; and
subjecting the transistor to an anneal process.

12. The method of claim 8, further comprising forming a gate contact in contact with the metal gate, the gate contact being partially surrounded by the dielectric cap and a dielectric layer on top of the dielectric cap and formed vertically above an active region of the transistor.

13. A semiconductor structure comprising:
a first metal gate and a second metal gate surrounding a first set of nanosheets and a second set of nanosheets respectively;
a source/drain region between the first set of nanosheets and the second set of nanosheets; and
a source/drain contact directly on top of the source/drain region,
wherein the source/drain contact has a first portion having a first width and a second portion having a second width, the second portion being on top of the first portion and the second width being narrower than the first width, the first width and the second width being measured in a length direction of the first metal gate.

14. The semiconductor structure of claim 13, further comprising a dielectric cap on top of the first metal gate and a dielectric layer on top of the dielectric cap, wherein a bottom of the second portion of the source/drain contact is at least below a bottom surface of the dielectric layer.

15. The semiconductor structure of claim 14, further comprising a gate contact, the gate contact being surrounded by the dielectric layer, by the dielectric cap, and in contact with the first metal gate.

16. The semiconductor structure of claim 15, wherein the first portion of the source/drain contact has a metallic liner at sidewalls thereof and the second portion of the source/drain contact is directly surrounded by a dielectric spacer, the metallic liner and the dielectric spacer are substantially vertically aligned.

17. The semiconductor structure of claim 16, wherein the second portion of the source/drain contact is separated from the gate contact by at least the dielectric spacer and a sidewall gate spacer that surrounds the first metal gate.

18. The semiconductor structure of claim 17, wherein the dielectric spacer and the sidewall gate spacer are separated by a dielectric liner.

19. The semiconductor structure of claim 16, wherein the dielectric spacer has a thickness H2 ranging from about 1 nm to about 5 nm while the second portion of the source/drain contact and the gate contact are separated by about 5 nm to about 9 nm.

20. The semiconductor structure of claim 15, wherein the dielectric layer has a thickness H0 ranging from about 10 nm to about 25 nm.
